(19) United States
(12) Patent Application Publication
(10) Pub. No.: US 2007/0122943 A1
(43) Pub. Date: May 31, 2007

(54) Method of making semiconductor package having exposed heat spreader

(76) Inventors: Chee Seng Foong, Selangor (MY); Wia Yew Lo, Selangor (MY)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 11/290,298

(22) Filed: Nov. 30, 2005

(51) Int. Cl. H01L 21/00

(52) U.S. Cl. 438/122

(57) ABSTRACT

A method of making a semiconductor package (50) includes attaching a bottom surface (54) of an integrated circuit (IC) die (52) to a base carrier (56) and electrically connecting the die (52) to the base carrier (56). A first surface (66) of a heat spreader (60) is attached to a top surface (58) of the die (52). The heat spreader includes a laminate (68) attached to a second surface (70) opposite the first surface (66). The die (52), the heat spreader (60), the laminate (68) and at least a portion of the base carrier (56) are encapsulated. The laminate (68) is detached from the heat spreader (60), which exposes the second surface (70) of the heat spreader (60).

### BACKGROUND OF THE INVENTION

The present invention relates to the packaging of integrated circuits (ICs) and more particularly to a method of making a semiconductor package having an exposed heat spreader.

Package reliability is compromised when heat generated within a semiconductor package is inadequately removed. To prevent package failure due to from overheating, a number of thermal management techniques have been devised. One common thermal management technique involves the use of a heat spreader to dissipate the heat generated by an integrated circuit (IC) die. FIG. 1 shows a conventional semiconductor package 10 with an exposed heat spreader 12. The semiconductor package 10 comprises an IC die 14 attached and electrically connected to a top surface 16 of a substrate 18. More particularly, the IC die 14 is attached to the substrate 18 with a die attach material 20, and electrically connected to the substrate 18 via a plurality of wire bonded wires 22. The heat spreader 12 is placed over the IC die 14 and is attached to the substrate 18 with a heat spreader attach material 24. The IC die 14, the wire bonded wires 22, a portion of the substrate 18 and a portion of the heat spreader 12, including its sides 26, are encapsulated with a molding compound 28. A plurality of solder balls 30 is attached to a bottom surface 32 of the substrate 18. During the encapsulation process, a substantial clamping pressure is applied to the heat spreader 12 to prevent flashing or bleeding of the molding compound 28. To prevent the IC die 14 from cracking as a result of the high compressive stress exerted on the heat spreader 12, the IC die 14 is separated from the heat spreader 12 by a layer of the molding compound 28 as shown in FIG. 1. However, as the molding compound 28 is typically a poor thermal conductor, the rate at which heat is conducted from the IC die 14 through the molding compound 28 to the heat spreader 12 is usually slower than that at which it is generated. Hence, the heat generated by the IC die 14 is often not adequately removed, and the semiconductor package 10 tends to fail due to overheating.

In view of the foregoing, it would be desirable to have a method of making a semiconductor package having an exposed heat spreader directly attached to an IC die that is capable of effectively dissipating heat generated by the IC die.

### BRIEF DESCRIPTION OF THE DRAWINGS

The following detailed description of preferred embodiments of the invention will be better understood when read in conjunction with the appended drawings. The present invention is illustrated by way of example and is not limited by the accompanying figures, in which like references indicate similar elements. It is to be understood that the drawings are not to scale and have been simplified for ease of understanding the invention.

FIG. 1 is an enlarged cross-sectional view of a conventional semiconductor package with an exposed heat spreader;

FIG. 2 is an enlarged cross-sectional view of a plurality of integrated circuit (IC) dice having respective bottom surfaces attached to a base carrier and respective top surfaces attached to a heat spreader in accordance with an embodiment of the present invention;

FIG. 3 is an enlarged top plan view of a patterned adhesive layer in accordance with an embodiment of the present invention;

FIG. 4 is an enlarged top plan view of a patterned adhesive layer in accordance with another embodiment of the present invention;

FIG. 5 is an enlarged cross-sectional view of the dice and the heat spreader of FIG. 2 encapsulated with an encapsulant;

FIG. 6 is an enlarged cross-sectional view of the base carrier of FIG. 5 having a plurality of solder balls attached thereto;

FIG. 7 is an enlarged cross-sectional view of the heat spreader of FIG. 6 being detached from a laminate to expose a surface thereof;

FIG. 8 is an enlarged cross-sectional view of a semiconductor package formed in accordance with an embodiment of the present invention; and

FIG. 9 is an enlarged cross-sectional view of a semiconductor package formed in accordance with another embodiment of the present invention.

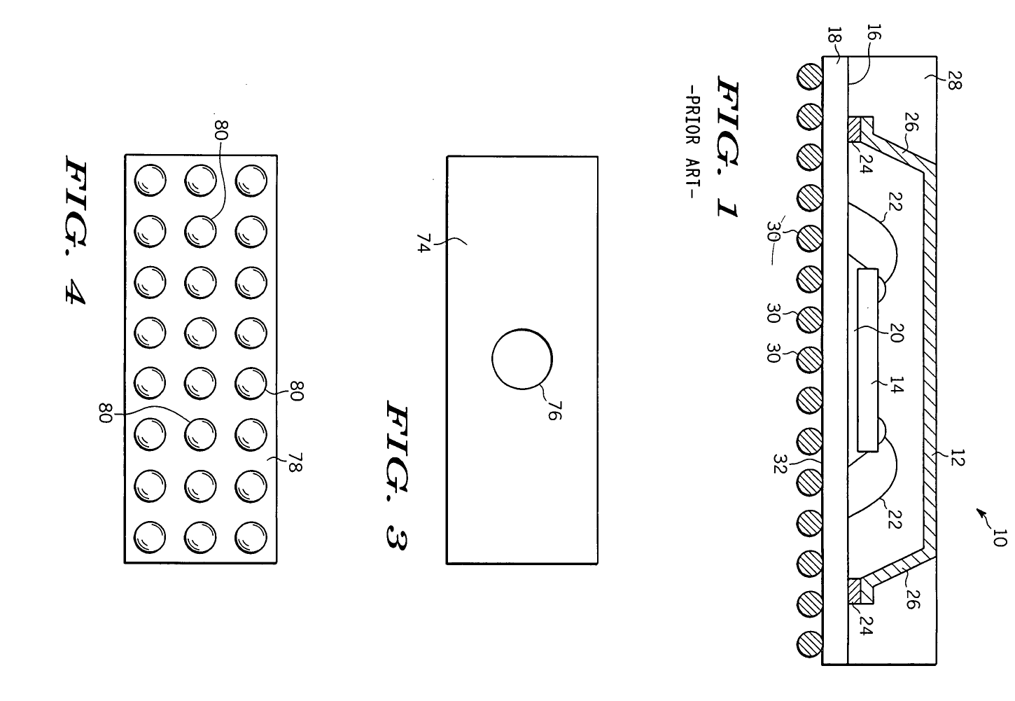

### DETAILED DESCRIPTION OF THE INVENTION

The detailed description set forth below in connection with the appended drawings is intended as a description of the presently preferred embodiments of the invention, and is not intended to represent the only form in which the present invention may be practiced. It is to be understood that the same or equivalent functions may be accomplished by different embodiments that are intended to be encompassed within the spirit and scope of the invention. In the drawings, like numerals are used to indicate like elements throughout.

The present invention provides a method of making a semiconductor package including the steps of attaching a bottom surface of an integrated circuit (IC) die to a base carrier and electrically connecting the die to the base carrier. A first surface of a heat spreader is attached to a top surface of the die. The heat spreader has a laminate attached to a second surface thereof. The die, the heat spreader, the laminate and at least a portion of the base carrier are encapsulated. The laminate is detached from the heat spreader, thereby exposing the second surface of the heat spreader.

The present invention also provides a method of making a plurality of semiconductor packages including the steps of attaching respective bottom surfaces of a plurality of integrated circuit (IC) dice to a base carrier and electrically connecting the dice to the base carrier. Respective bottom surfaces of a plurality of heat spreaders are attached to respective top surfaces of the dice. The heat spreaders have a laminate attached to respective top surfaces thereof. The dice, the heat spreaders, the laminate and at least a portion of the base carrier are encapsulated. The laminate is detached from the heat spreaders, thereby exposing the top surfaces and side surfaces of the heat spreaders.

The present invention further provides a method of making a plurality of semiconductor packages including the steps of attaching respective bottom surfaces of a plurality of integrated circuit (IC) dice to a base carrier and electrically connecting the dice to the base carrier. Respective first surfaces of a plurality of heat spreaders are attached to respective top surfaces of the dice. The heat spreaders have a laminate attached to respective second surfaces thereof. The dice, the heat spreaders, the laminate and at least a portion of the base carrier are encapsulated. A singulating operation is performed to separate adjacent ones of the dice such that side surfaces of the heat spreaders are exposed by the singulating operation. The laminate is detached from the heat spreaders, which exposes the second surfaces of the heat spreaders.

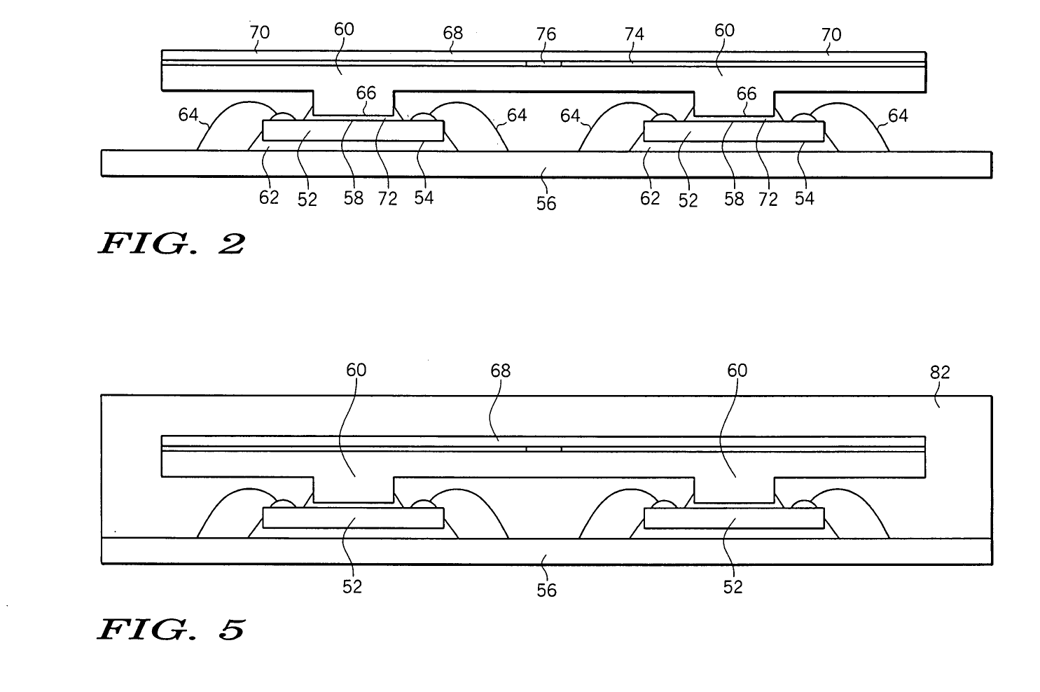

FIGS. 2 and 5-7 are enlarged cross-sectional views that illustrate a method of making a plurality of semiconductor packages 50 in accordance with an embodiment of the present invention. The semiconductor packages 50 preferably are made with a Molded Array Process (MAP), thereby achieving high throughput.

Referring now to FIG. 2, a plurality of integrated circuit (IC) dice 52 having respective bottom surfaces 54 attached to a base carrier 56 and respective top surfaces 58 attached to respective ones of a plurality of heat spreaders 60 is shown. The dice 52 are electrically connected to the base carrier 56.

The dice 52 may be processors, such as digital signal processors (DSPs), special function circuits, such as memory address generators, or circuits that perform any other type of function. The dice 52 are not limited to a particular technology such as CMOS, or derived from any particular wafer technology. Further, the present invention can accommodate dice of various sizes, as will be understood by those of skill in the art. A typical example is a memory die having a size of about 15 mm by 15 mm. The dice 52 may be attached to the base carrier 56 with an adhesive material 62. The adhesive material 62 may be any suitable adhesive material, such as an adhesive tape, a thermo-plastic adhesive, an epoxy material, or the like. Such adhesives for attaching an IC die 52 to a base carrier 56 are well known to those of skill in the art. The dice 52 are electrically connected to the base carriers 56 via a plurality of wire bonded wires 64. The wires 64 may be made of gold (Au) or other electrically conductive materials as are known in the art and commercially available. As can be seen from FIG. 2, the wire bonded wires 64 in this particular embodiment are attached to the IC dice 52 with ball bonds. However, it should be understood that the present invention is not limited to a particular wire bonding technique or to wire bond type connections. In alternative embodiments, the dice 52 may be, for example, electrically connected to the base carrier 56 via flip chip bumps (see flip chip bumps 156 in FIG. 9, described below).

Respective first or bottom surfaces 66 of the heat spreaders 60 are attached to the respective top surfaces 58 of the dice 52. The heat spreaders 60 have a laminate 68 attached to respective second or top surfaces 70 thereof. A conductive adhesive 72 such as, for example, silicone is used to attach the respective heat spreaders 60 to respective ones of the dice 52. The conductive adhesive 72 is dispensed onto the respective top surfaces 58 of the dice 52 then the heat spreaders 60 are placed, as a gang, on the respective top surfaces 58 of the dice 52 and attached by curing the conductive adhesive 72. Because the heat spreaders 60 are attached to the dice 52, and not to the base carrier 56, no restrictions are imposed on the design of the base carrier 56. Therefore, existing base carriers can be used in the present invention. The heat spreaders 60 are made of a thermally conductive material such as, for example, copper, aluminium or alloys thereof, while the laminate 68 is preferably a high temperature tape and has a thickness of about 50 microns.

A patterned adhesive layer 74 is used to attach the laminate 68 to the top surfaces 70 of the heat spreaders 60. The adhesive layer 74 may be made of silicone and is patterned to facilitate subsequent separation of the laminate 68 from the heat spreaders 60, as described below. In this particular embodiment, the patterned adhesive layer 74 comprises an adhesive tape having at least one perforation 76. FIG. 3 is an enlarged top plan view of the patterned adhesive layer 74 of FIG. 2. As can be seen, the adhesive layer 74 includes one (1) perforation 76 proximate to a centre thereof. In another embodiment shown in FIG. 4, the patterned adhesive layer 78 includes a plurality of perforations 80 distributed throughout the adhesive layer 78. Accordingly, it should be understood that the present invention is not limited by the number or location of the perforations in the adhesive layer.

Referring now to FIG. 5, the dice 52, the heat spreaders 60, the laminate 68 and at least a portion of the base carrier 56 of FIG. 2 are encapsulated with an encapsulant 82. A molding operation such as, for example, an injection molding process is performed to encapsulate the dice 52, the heat spreaders 60, the laminate 68 and the portion of the base carrier 56. The encapsulant 82 may comprise well known commercially available molding materials such as plastic or epoxy. As can be seen, the heat spreaders 60 are completely encapsulated by the encapsulant 82 and are not in direct contact with the mold during the molding operation. Consequently, the heat spreaders 60 and the dice 52 to which they are attached are protected from the clamping pressure applied during the molding operation by the encapsulant 82. This reduces the risk of die cracking during the molding operation.

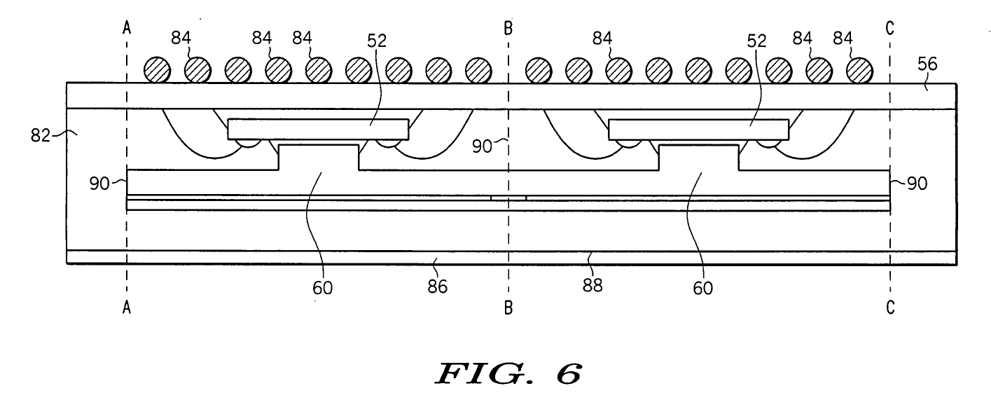

Referring now to FIG. 6, a plurality of solder balls 84 is attached to the base carrier 56. As shown in FIG. 6, the encapsulated dice 52, heat spreaders 60 and base carrier 56 are positioned in a “dead bug” orientation (upside-down) for the attachment of the solder balls 84. The solder balls 84 may be attached to the base carrier 56 using known solder ball attach processes. The encapsulated dice 52, heat spreaders 60 and base carrier 56 are mounted on a tape 86, such as a Mylar® film as part of a singulating operation, for example, saw singulation. More particularly, the tape 86 is attached to an exposed surface 88 of the encapsulant 82 parallel to the base carrier 56. The singulating operation is performed along the vertical lines A-A, B-B and C-C to separate adjacent ones of the dice 52 and expose side surfaces 90 of the heat spreaders 60. In this particular example, the singulating operation is performed after the attachment of the solder balls 84 to the base carrier 56. However, those of skill in the art will understand that the singulating operation can also be performed before the attachment of the solder balls 84 to the base carrier 56.

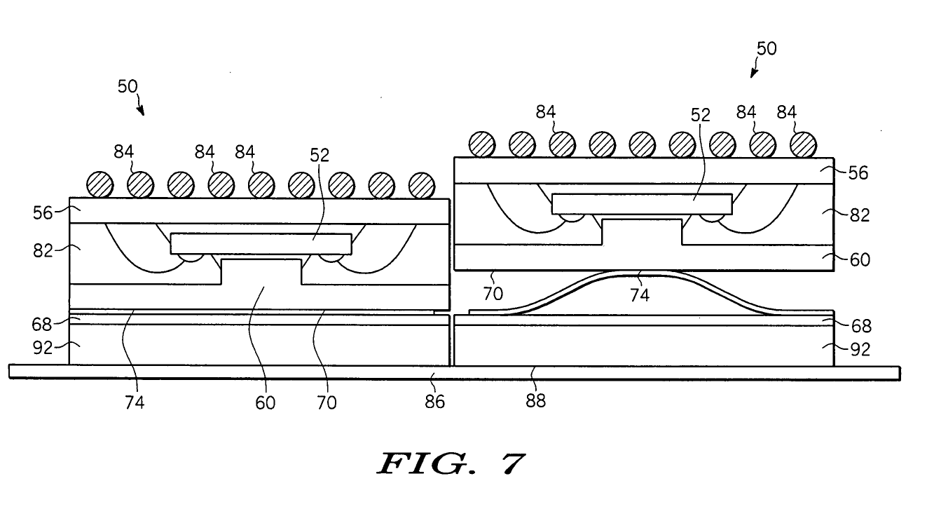

Referring now to FIG. 7, the heat spreaders 60 are detached from the laminate 68 to expose the top surfaces 70 of the heat spreaders 60. More particularly, each of the semiconductor packages 50 is picked up, and de-taped in the pick-up process to expose the top surfaces 70 of the heat spreaders 60. As shown in FIG. 7, a top portion or layer 92 of the encapsulant 82 is peeled off together with the laminate 68 to expose the top surfaces 70 of the heat spreaders 60. As can be seen, the tape 86 is used to detach the laminate 68 from the heat spreaders 60. The tape 86 facilitates the detachment process by adhering to the encapsulant 82. Because a layer 92 of the encapsulant 82 is peeled off, ultra-thin semiconductor packages 50 can be formed with the present invention. Bleeding and flashing of the encapsulant 82 over the top surfaces 70 of the heat spreaders 60 are prevented because the laminate 68 protects the top surfaces 70 of the heat spreaders 60 during the encapsulation process.

Although FIGS. 2 and 5-7 show only two (2) dice 52, it will be understood that more or fewer dice 52 may be attached to the base carrier 56, depending on the size of the base carrier 56, the size of the dice 52, and the required functionality of the resulting semiconductor packages 50.

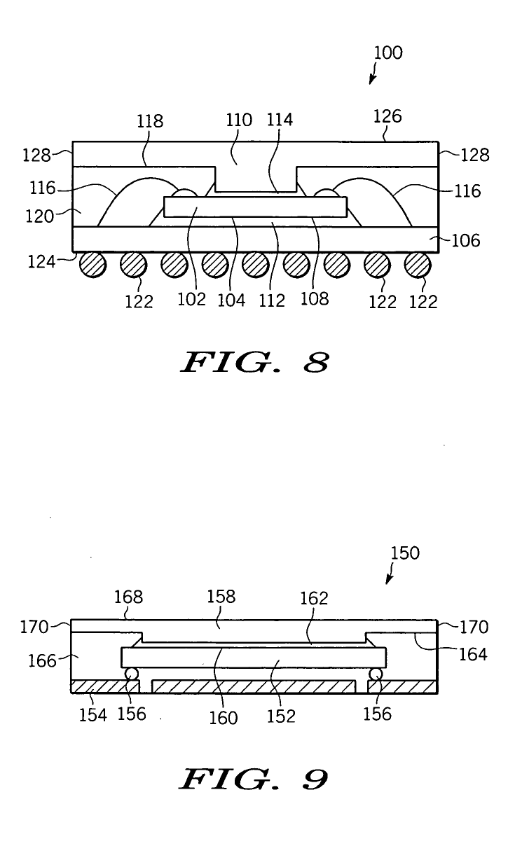

Referring now to FIG. 8, an enlarged cross-sectional view of a semiconductor package 100 formed in accordance with the procedure described above is shown. The semiconductor package 100 comprises an integrated circuit (IC) die 102 attached on a bottom surface 104 to a base carrier 106 and on a top surface 108 to a heat spreader 110. In this embodiment, the base carrier 106 is a substrate. The IC die 102 is attached to the substrate 106 with an adhesive material 112, while the heat spreader 110 is attached to the IC die 102 with a conductive adhesive 114. The IC die 102 is electrically connected to the substrate 106 via a plurality of wire bonded wires 116. The IC die 102, a bottom surface or underside 118 of the heat spreader 110 and at least a portion of the substrate 106 (i.e., a top surface of the substrate 106) are encapsulated with an encapsulant 120. A plurality of solder balls 122 is attached to an underside 124 of the substrate 106. As shown in FIG. 8, a top surface 126 and side surfaces 128 of the heat spreader 110 are exposed.

Referring now to FIG. 9, an enlarged cross-sectional view of a semiconductor package 150 formed in accordance with another embodiment of the present invention is shown. The semiconductor package 150 comprises an integrated circuit (IC) die 152 placed on a base carrier 154, in this embodiment, a lead frame. The IC die 152 is electrically connected to the lead frame 154 via flip chip bumps 156. A heat spreader 158 is attached to a top surface 160 of the IC die 152 with a conductive adhesive 162. The IC die 152, a bottom surface or underside 164 of the heat spreader 158 and at least a portion of the lead frame 154 are encapsulated with an encapsulant 166, leaving a top surface 168 and side surfaces 170 of the heat spreader 158 exposed. The semiconductor package 150 is strengthened by having top and bottom surfaces made of metal.

As can be seen from FIGS. 8 and 9, the heat spreader in the present invention is directly attached to the IC die. Consequently, a direct thermal path is provided from the IC die to the heat spreader. This facilitates dissipation of the heat generated by the IC die, thereby reducing the likelihood of package failure due to overheating.

Further, because the heat spreader of the present invention is exposed to the ambient environment on the top and side surfaces, the semiconductor package of the present invention provides a substantial surface area for the convection of heat away from the semiconductor package. This enhances the thermal performance of the semiconductor packages made in accordance with the present invention. With improved thermal performance, the power capability of the semiconductor packages can be increased, for example, from about 2 Watts (W) to about 3 W. Alternatively, the temperature of the semiconductor packages can be reduced, for example, by about half.

As is evident from the foregoing discussion, the present invention provides an inexpensive method for volume production of reliable and thermally enhanced semiconductor packages. The present invention can be implemented using current semiconductor assembly equipment. Hence, there is no need for additional capital investment. Package rigidity and reliability are enhanced with the provision of the heat spreader. The heat spreader of the present invention is simply shaped, and is therefore easy to manufacture and can be readily incorporated into the assembly process. Additionally, the heat spreader design is suitable for use in all package types and sizes.

The description of the preferred embodiments of the present invention have been presented for purposes of illustration and description, but are not intended to be exhaustive or to limit the invention to the forms disclosed. It will be appreciated by those skilled in the art that changes could be made to the embodiments described above without departing from the broad inventive concept thereof. For example, the present invention is applicable to molded packages, including but not limited to MapBGA, PBGA, QFN, QFP and FC devices. In addition, the die sizes and the dimensions of the steps may vary to accommodate the required package design. It is understood, therefore, that this invention is not limited to the particular embodiments disclosed, but covers modifications within the spirit and scope of the present invention as defined by the appended claims.

1. A method of making a semiconductor package, comprising:
attaching a bottom surface of an integrated circuit (IC) die to a base carrier;
electrically connecting the die to the base carrier;
attaching a first surface of a heat spreader to a top surface of the die, wherein the heat spreader has a laminate attached to a second surface thereof;
encapsulating the die, the heat spreader, the laminate and at least a portion of the base carrier; and
detaching the laminate from the heat spreader, thereby exposing the second surface of the heat spreader.

2. The method of making a semiconductor package of claim 1, wherein side surfaces of the heat spreader are exposed.

3. The method of making a semiconductor package of claim 1, wherein a tape is used to detach the laminate from the heat spreader.

4. The method of making a semiconductor package of claim 1, wherein a patterned adhesive layer is used to attach the laminate to the heat spreader.

5. The method of making a semiconductor package of claim 4, wherein the patterned adhesive layer comprises an adhesive tape having at least one perforation.

6. The method of making a semiconductor package of claim 1, wherein a conductive adhesive is used to attach the heat spreader to the die.

7. The method of making a semiconductor package of claim 1, further comprising attaching a plurality of solder balls to the base carrier.

8. The method of making a semiconductor package of claim 1, wherein the die is electrically connected to the base carrier via a plurality of wire bonded wires.

9. The method of making a semiconductor package of claim 1, wherein the die is electrically connected to the base carrier via flip chip bumps.

10. A method of making a plurality of semiconductor packages, comprising:
attaching respective bottom surfaces of a plurality of integrated circuit (IC) dice to a base carrier;
electrically connecting the dice to the base carrier;
attaching respective bottom surfaces of a plurality of heat spreaders to respective top surfaces of the dice, wherein the heat spreaders have laminates attached to respective top surfaces thereof;
encapsulating the dice, the heat spreaders, the laminate and at least a portion of the base carrier; and
detaching the laminates from the heat spreaders, such that at least the top surfaces of the heat spreaders are exposed.

11. The method of making a plurality of semiconductor packages of claim 10, wherein a tape is used to detach the laminate from the heat spreaders.

12. The method of making a plurality of semiconductor packages of claim 10, wherein a patterned adhesive layer is used to attach the laminate to the heat spreaders.

13. The method of making a plurality of semiconductor packages of claim 12, wherein the patterned adhesive layer comprises an adhesive tape having at least one perforation.

14. The method of making a plurality of semiconductor packages of claim 10, wherein a conductive adhesive is used to attach the respective heat spreaders to respective ones of the dice.

15. The method of making a plurality of semiconductor packages of claim 10, further comprising attaching a plurality of solder balls to the base carrier.

16. The method of making a plurality of semiconductor packages of claim 10, wherein the dice are electrically connected to the base carrier via a plurality of wire bonded wires.

17. The method of making a plurality of semiconductor packages of claim 10, wherein the dice are electrically connected to the base carrier via flip chip bumps.

18. The method of making a plurality of semiconductor packasges of claim 10, further comprising performing a singulating operation to separate adjacent ones of the dice, wherein side surfaces of the heat spreaders are exposed by the singulating operation.

19. A method of making a plurality of semiconductor packages, comprising:
attaching respective bottom surfaces of a plurality of integrated circuit (IC) dice to a base carrier;
electrically connecting the dice to the base carrier;
attaching respective first surfaces of a plurality of heat spreaders to respective top surfaces of the dice, wherein the heat spreaders have a laminate attached to respective second surfaces thereof;
encapsulating the dice, the heat spreaders, the laminate and at least a portion of the base carrier;
performing a singulating operation to separate adjacent ones of the dice, wherein side surfaces of the heat spreaders are exposed by the singulating operation; and
detaching the laminate from the heat spreaders, thereby exposing the second surfaces of the heat spreaders.

20. The method of making a plurality of semiconductor packages of claim 19, wherein a tape is used to detach the laminate from the heat spreaders.
